(19) United States
(12) Patent Application Publication
(10) Pub. No.: US 2025/0372421 A1
(43) Pub. Date: Dec. 4, 2025

(54) SYSTEMS FOR MANUFACTURING A SEMICONDUCTOR DEVICE AND RELEVANT METHODS

(71) Applicant: NANYA TECHNOLOGY CORPORATION, NEW TAIPEI CITY (TW)

(72) Inventor: JUNG-TZU PENG, NEW TAIPEI CITY (TW)

(21) Appl. No.: 18/742,084

(22) Filed: Jun. 13, 2024

Related U.S. Application Data
(62) Division of application No. 18/676,846, filed on May 29, 2024.

(51) Int. Cl. H01L 21/67; B24B 7/22; H01L 21/687

(52) U.S. Cl. CPC H01L 21/67288; B24B 7/228; H01L 21/68785

(57) ABSTRACT

A system and a method for manufacturing a semiconductor device are provided. The system includes a processor, a stage for supporting a first wafer, and a polishing device. The stage is configured to sense characteristic data of a first surface of the first wafer, wherein the stage is electrically coupled to the processor and configured to transmit the sensed characteristic data of the first surface of the first wafer to the processor. The polishing device is electrically coupled to the processor and configured to remove foreign objects from the first surface of the first wafer based on the sensed characteristic data.

### CROSS-REFERENCE TO RELATED APPLICATION

This application is a divisional application of U.S. Non-Provisional application Ser. No. 18/676,846 filed May 29, 2024, which is incorporated herein by reference in its entirety.

### TECHNICAL FIELD

The present disclosure relates to a system and a method of manufacturing a semiconductor device, and more particularly, to a system and a method for flattening a backside of wafers.

### DISCUSSION OF THE BACKGROUND

To manufacture a semiconductor device, a wafer may undergo multiple photolithography processes, including at least photoresist, exposure, development, etching, deposition, diffusion, etc. During some of the processes, such as etching, deposition, or diffusion, foreign objects/particles, film residue, uneven film, or other defects may remain on the backside of the wafer, whereby exposure processes may experience defocusing that can impair imaging quality, impacting imaging dimensions and pattern profiles of the wafer. A means of flattening the backside surface of a wafer is thus called for.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a system for manufacturing a semiconductor device. The system includes a processor, a stage for supporting a first wafer, and a polishing device. The stage is configured to sense characteristic data of a first surface of the first wafer, wherein the stage is electrically coupled to the processor and configured to transmit the sensed characteristic data of the first surface of the first wafer to the processor. The polishing device is electrically coupled to the processor and configured to remove foreign objects from the first surface of the first wafer based on the sensed characteristic data.

One aspect of the present disclosure provides a system for manufacturing a semiconductor device. The system includes a processor coupled to a non-transitory computer-readable medium storing computer-executable instructions, a stage including piezoelectric elements and electrically coupled to the processor, and a flattening apparatus electrically coupled to the processor and configured to hold the first wafer. The piezoelectric elements are configured to collect data of a first surface of a first wafer supported by the stage. The processor executes the computer-executable instructions and cause the flattening apparatus to flatten the first surface of the first wafer based on data collected from the first surface of the first wafer.

One aspect of the present disclosure provides a method for manufacturing a semiconductor device. The method includes: providing a wafer, placing the wafer on a vacuum stage, wherein a first surface of the wafer is in contact with the vacuum stage, the vacuum stage sensing and collecting based on data of the first surface of the wafer, performing a photoresist process on the wafer and a polishing device flattening the first surface of the wafer based on data of said surface.

The embodiments of the present disclosure provide systems and methods for flattening a backside of a wafer before exposure to avoid undesired variations from foreign objects/particles, film residue, uneven film, and other contaminants and defects on the backside of the wafer as introduced by etching, deposition, diffusion, or the like, which lead to defocusing at some parts of the wafer.

The system of the present disclosure provides a supporting stage (such as a vacuum stage) and a flattening apparatus (such as a polishing device). The supporting stage is capable of detecting and collecting the flatness of the backside of the wafer and the corresponding location. The supporting stage can include piezoelectric elements configured to sense a topography of the backside of the wafer. For example, the piezoelectric elements can be configured to detect deformations on the backside of the wafer. The deformations on the backside of the wafer can be resulted from the foreign objects or uneven film. The piezoelectric data corresponding to the deformations can be converted to data associated with the flatness and location, such that the supporting stage can collect the flatness and location data of the backside of the wafer.

Gathered data regarding flatness and location can be transmitted to the flattening apparatus, which can polish the backside of the wafer accordingly, based on the topography thereof under different pressures. That is, the flattening apparatus can polish each portion of the backside of the wafer, in response to a respective deformation and the corresponding location. Accordingly, the result is a flattened surface with improved flatness, such that undesired defocus issues in the exposure processes can be reduced. Comparing to fixed pressure polishing, the disclosed system also avoids over polishing that can damage the wafer. Thus, the performance of the exposure processes, for example, the quality of the imaging dimensions and the pattern profiles of the wafer, can be improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It can also be appreciated by those skilled in the art that such equivalent constructions do not depart from the spirit and scope of the disclosure as set forth in the appended claims.

### BRIEF DESCRIPTION OF THE DRA WINGS

A more complete understanding of the present disclosure may be derived by referring to the detailed description and claims when considered in connection with the Figures, where like reference numbers refer to similar elements throughout the Figures, and:

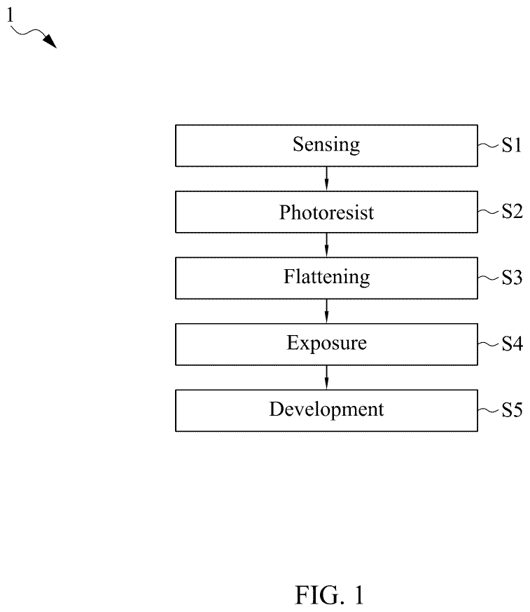

FIG. 1 is a flowchart of a method for manufacturing a semiconductor device, in accordance with some embodiments of the present disclosure.

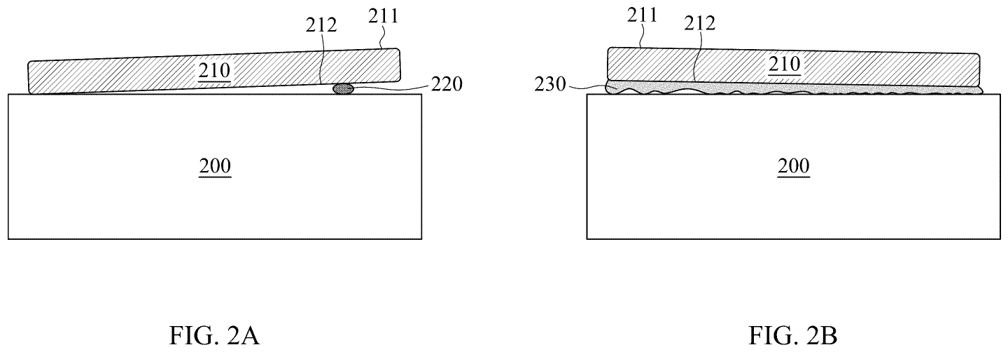

FIG. 2A shows a problematic situation of a wafer, in accordance with some embodiments of the present disclosure.

FIG. 2B shows a problematic situation of a wafer, in accordance with some embodiments of the present disclosure.

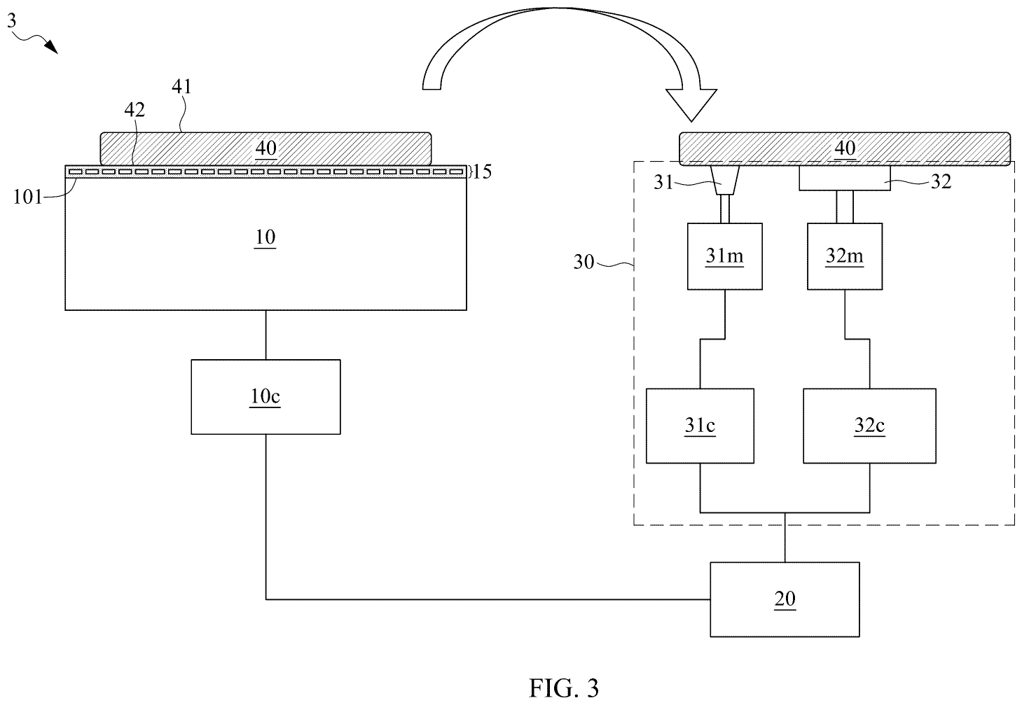

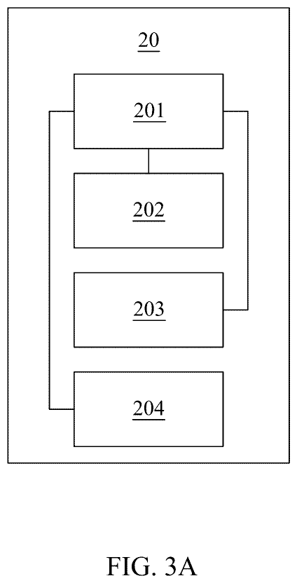

FIG. 3 is a schematic diagram of a system for manufacturing a semiconductor device, in accordance with some embodiments of the present disclosure.

FIG. 3A is a schematic diagram showing a computer device, in accordance with some embodiments of the present disclosure.

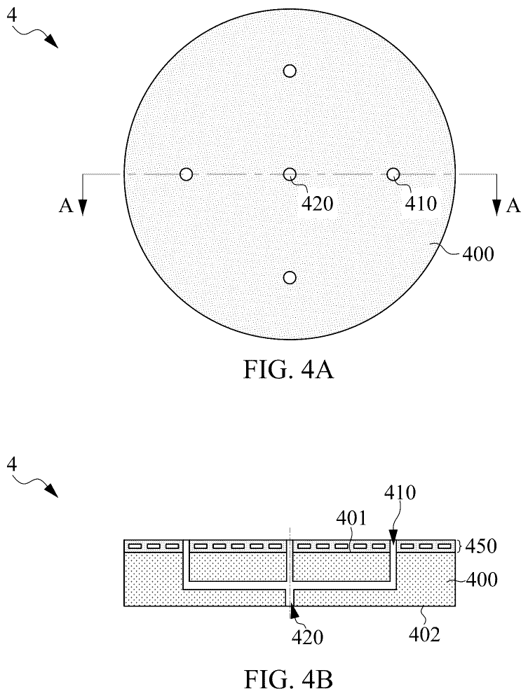

FIG. 4A is a schematic top view of a vacuum stage, in accordance with some embodiments of the present disclosure.

FIG. 4B is a cross-section of the vacuum stage along line A-A of FIG. 4A, in accordance with some embodiments of the present disclosure.

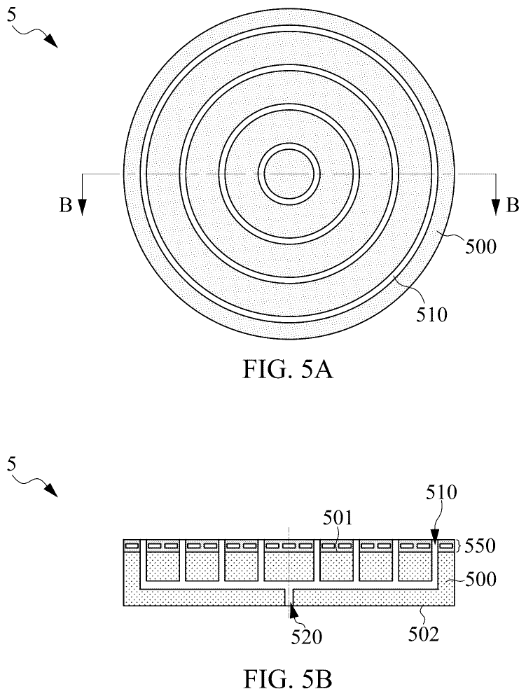

FIG. 5A is a schematic top view of a vacuum stage, in accordance with some embodiments of the present disclosure.

FIG. 5B is a cross-section of the vacuum stage along line B-B of FIG. 5A, in accordance with some embodiments of the present disclosure.

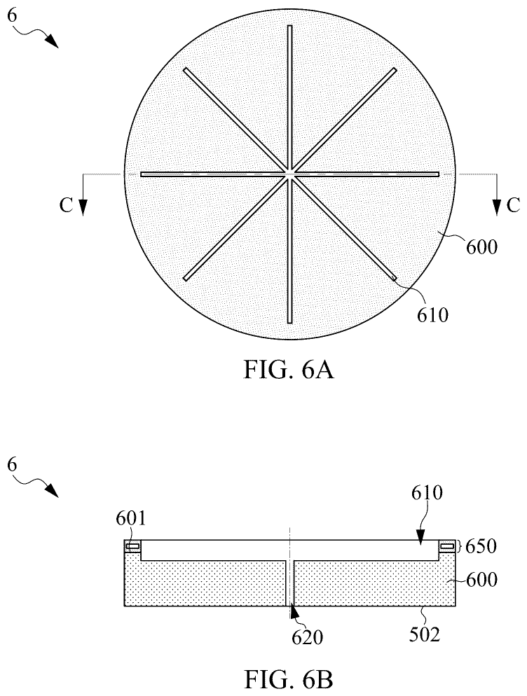

FIG. 6A is a schematic top view of a vacuum stage, in accordance with some embodiments of the present disclosure.

FIG. 6B is a cross-section of the vacuum stage along line C-C of FIG. 6A, in accordance with some embodiments of the present disclosure.

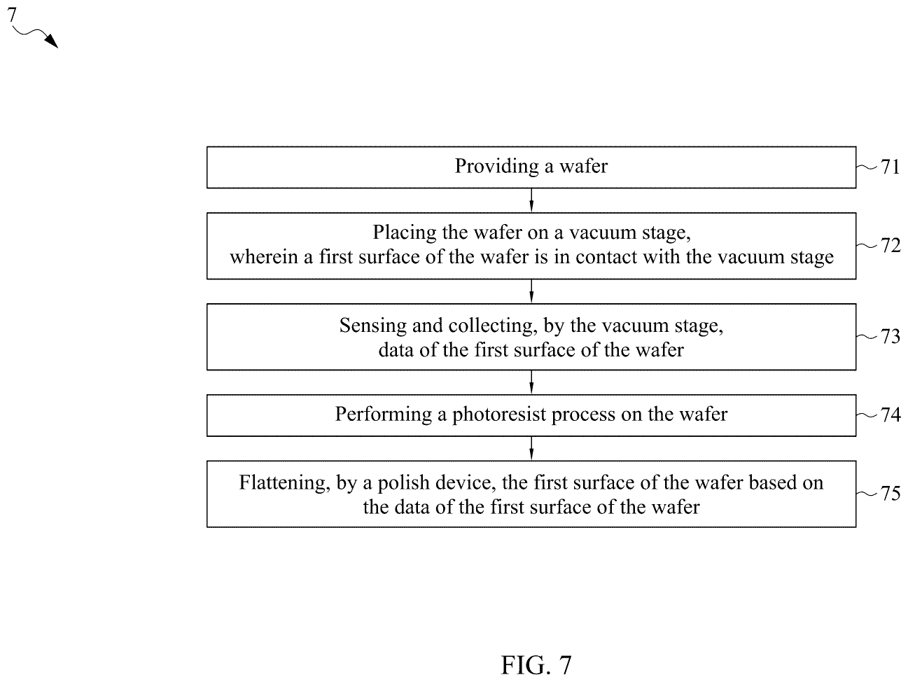

FIG. 7 is a flowchart of a method for manufacturing a semiconductor device, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

It should be noted that the term “about” modifying the quantity of an ingredient, component, or reactant of the present disclosure employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. In yet another aspect, the term “about” means within 10, 9, 8, 7, 6, 5, 4, 3, 2, or 1% of the reported numerical value.

FIG. 1 is a flowchart of a method 1 for manufacturing a semiconductor device, in accordance with some embodiments of the present disclosure. In some embodiments, the method 1 merely includes a photolithography process performed on a wafer. The photolithography process can at least include a photoresist, exposure, and development. In some embodiments, the wafer may comprise semiconductor devices thereon. The method 1 may be performed by an automated robotic wafer track system. In some embodiments, the wafer tracks may be used to carry wafers. Although not depicted in FIG. 1, it can be contemplated that the method 1 may further include steps of the photolithography process, such as cleaning, hot plate, cold plate, pre-baking, hard baking, etc.

The method 1 includes operations S1, S2, S3, S4, and S5. In operation S1, the wafer can be placed on a stage for sensing data of the wafer. Data may be a kind of characteristic data. Data may be associated with characteristics of the backside surface of the wafer. For example, data may include flatness, deformation on the backside of the wafer, and location of the backside of the wafer. In some embodiments, the stage can include a vacuum stage on which the wafer can be fixed thereon. In some embodiments, the wafer may be placed on the stage prior to subsequent operations. In some embodiments, before the operation S1, the wafer may be cleaned and prepared for the photolithography process, for example, being preheated to remove moisture.

The stage can include piezoelectric elements disposed on a top surface of the stage. When the wafer is placed on the stage, the backside of the wafer can contact the piezoelectric elements, such that the piezoelectric elements are configured to detect piezoelectric data associated with deformation on the backside surface of the wafer. Details of the stage are discussed in FIG. 3. In some embodiments, deformation on the backside of the wafer may be caused by foreign objects or uneven film on the backside of the wafer, possibly introduced during previous semiconductor processes. The foreign objects and uneven film are discussed in FIGS. 2A-2B. The piezoelectric data corresponding to deformation can be converted to data associated with flatness and location. Data regarding flatness and location can then be transmitted to a flattening apparatus used in operation S3.

In operation S2, a photoresist can be applied on the wafer. In some embodiments, the wafer can be covered with photoresist liquid by spin coating. The photoresist-coated wafer may then be prebaked on a hotplate to remove excess solvent. The photoresist may be a positive photoresist or a negative photoresist.

In operation S3, the backside of the wafer can be flattened based on data of the backside of the wafer. In some embodiments, operation S3 may be performed by a flattening apparatus (such as a polishing device). The flattening apparatus includes a polishing head configured to apply different pressures to different locations in response to the characteristic data (for example, deformation and corresponding locations) of the backside of the wafer, so that flatness of the backside of the polished wafer is improved. In particular, if deformation of a portion of the backside of the wafer is determined to exceed others based on the characteristic data, this portion may include foreign objects or film residue thereon. In such a case, the flattening apparatus will remove more at this portion under greater pressure. On the contrary, if deformation of another portion of the backside of the wafer is determined to be less than others based on the characteristic data, the flattening apparatus will polish at this portion under a lower pressure. Accordingly, the foreign objects and film residue can be removed, and the backside of the wafer can be flattened. Details of the flattening apparatus are discussed in FIG. 3.

In operation S4, an exposure can be performed on the wafer. In some embodiments, the photoresist of the wafer can be exposed to intense light through a patterned photomask. For example, the wafer may be exposed to deep ultraviolet (DUV), extreme ultraviolet (EUV) light, or other suitable light. In some embodiments, the exposure to light may cause a chemical change that enables photomask patterns to be projected onto the photoresist.

In operation S5, a development process can be performed on the wafer after the exposure process. In some embodiments, a special solution, i.e., the developer, can be delivered on the wafer, such that some of the photoresist may be washed away to form a 3D pattern corresponding to the photomask. Accordingly, other semiconductor processes, such as etching, implantation, or the like, can then be performed on the wafer to form the semiconductor devices.

FIG. 2A shows a problematic situation of a wafer 210, in accordance with some embodiments of the present disclosure. Referring to FIG. 2A, the wafer 210 can be placed on the exposure stage 200. The wafer 210 has a top surface 211 and a bottom surface 212 opposite to the top surface 211. In some embodiments, the top surface 211 may be the front side of the wafer 210, and the bottom surface 212 may be the backside of the wafer 210. When the wafer 210 is placed on the exposure stage 200, the bottom surface 212 faces the exposure stage 200.

In some embodiments, the wafer 210 may include one or more foreign objects 220 disposed on the bottom surface 212. The foreign objects 220 are attached to the bottom surface 212. In some embodiments, the foreign objects 220 may be introduced by etching, deposition, or diffusion performed on the wafer 210. In some embodiments, the foreign objects 220 may include particles at μm, nm, or even smaller levels. In some embodiments, the foreign objects 220 may be solid particles. In some embodiments, the foreign objects 220 may be film residue. The wafer 210 may be unstable on the exposure stage 200 due to the foreign objects 220, and cause defocus in the exposure processes.

Accordingly, the foreign objects 220 should be removed before exposure. The present disclosure provides a system and method for removing the foreign objects 220 on the bottom surface 212 of the wafer 210 before exposure based on deformation caused by the foreign objects 220.

FIG. 2B shows a problematic situation of a wafer 210, in accordance with some embodiments of the present disclosure. FIG. 2B is similar to FIG. 2A, other than including a film 230 distributed unevenly on the bottom surface 212, presenting uneven thickness thereof. In some embodiments, the film 230 may be film residue. In other words, the film 230 may cover part of the bottom surface 212 and expose other parts.

In some embodiments, the film 230 may be introduced by etching, deposition, or diffusion performed on the wafer 210. The wafer 210 may be unstable on the exposure stage 200 due to the uneven film 230, and cause defocus in the exposure processes.

Accordingly, the uneven film 230 should be removed or flattened before exposure. The present disclosure provides a system and method for flattening the film 230 on the bottom surface 212 of the wafer 210 before exposure based on deformation caused by the film 230.

FIG. 3 is a schematic diagram of a system 3 for manufacturing a semiconductor device, in accordance with some embodiments of the present disclosure. The system 3 may be an automated robotic wafer track system, which may include preparing unit, detection unit, photoresist unit, flattening unit, exposure unit, development unit, etc. Each units may include corresponding apparatus and can be connected by tracks carrying wafers.

Referring to FIG. 3, the system 3 includes a stage 10, a computer device 20, and a flattening apparatus 30. For clarity, FIG. 3 merely shows a detection unit 3A and flattening unit 3B. In some embodiments, the detection unit 3A can include the stage 10 for supporting wafers. The flattening unit 3B can include the flattening apparatus 30 for flattening the backside of wafers. In some embodiments, the detection unit 3A and the flattening unit 3B can be connected by wafer tracks and connected to the computer device 20. The computer device 20 can be configured to control units (such as the detection unit 3A and flattening unit 3B) of the system 3.

The stage 10 can be configured to support a wafer 40. In some embodiments, the wafer 40 has a top surface 41 and a bottom surface 42 opposite to the top surface 41. The top surface 41 can be the front side of the wafer 40 and the bottom surface 42 be the backside. In some embodiments, the wafer 40 may be a semiconductor wafer. In some embodiments, the wafer 40 can be carried by the wafer track (not shown) to the stage 10 of the detection unit 3A. In some embodiments, the stage 10 has a top surface 101. The bottom surface 42 of the wafer 40 can be placed on the top surface 101 of the stage 10.

In some embodiments, the stage 10 can be a vacuum stage for fixing the wafer 40. For example, the stage 10 can include one or more exhaust vents or exhaust channels recessed from the top surface 101. To fix the wafer 40, negative pressure can be created in the exhaust vents through a vacuum pump (not shown). Details of the vacuum stage are discussed in FIGS. 4A-4B, 5A-5B, and 6A-6B.

The stage 10 can be configured to be connected to a controller 10c. The controller 10c can be configured to control the operations of the stage 10, such as a vacuum operation, detecting operation, cooling operation, or other suitable operations. In some embodiments, the controller 10c can be configured to communicate with other elements in the system 3. For example, the controller 10c can be electrically connected to the computer device 20. The controller 10c can be configured to transmit data of the stage 10 to the computer device 20. The controller 10c can be configured to receive instructions from the computer device 20. In some embodiments, the computer device 20 can be configured to cause the stage 10 to perform operations through the controller 10c.

In some embodiments, the stage 10 can be configured to sense (or detect) data of the bottom surface 42 of the wafer 40. The stage 10 can be electrically coupled to the computer device 20 and configured to transmit the sensed data of the bottom surface 42 of the wafer 40 to the computer device 20. In some embodiments, data of the bottom surface 42 of the wafer 40 can be characteristic data associated with the bottom surface 42 of the wafer 40.

The stage 10 can include piezoelectric elements 15 disposed on the top surface 101 of the stage 10. In some embodiments, the piezoelectric elements 15 can be a layer covering the top surface 101 of the stage 10. Each of the piezoelectric elements can have an area in a range of 1 mm² to 100 mm² in a top view. In some embodiments, when the wafer 40 is placed on the stage 10, the piezoelectric elements 15 can contact the bottom surface 42 of the wafer 40. The piezoelectric elements 15 can be configured to detect and/or collect data of the bottom surface 42 of the wafer 40 supported by the stage 10. The piezoelectric elements 15 can be configured to sense deformation on the bottom surface 42 of the wafer 40. In some embodiments, the piezoelectric elements 15 can detect deformation on the wafer 40 in a μm, nm, or smaller scale. In some embodiments, the piezoelectric data detected by the piezoelectric elements 15 can be used to obtain a topography of the bottom surface 42 of the wafer 40. The piezoelectric data can be converted, by the controller 10c or the computer device 20, to data associated with the flatness and location of the bottom surface 42 of the wafer 40. Thus, the stage 10 could collect the flatness and location data of the bottom surface 42 of the wafer 40. In some embodiments, the data can then be transmitted to the computer device 20 via the controller 10c, and then be utilized in the flattening process conducted by the flattening apparatus 30.

In some embodiments, the wafer 40 can be transported to the flattening apparatus 30 of the flattening unit 3B. The detection process can be subsequent to the flattening process. In some embodiments, the wafer 40 can be transported to the flattening apparatus 30 from the stage 10 with or without performing semiconductor processes (such as photoresist coating process) on it. In another embodiments, the detection process can be subsequent to the flattening process.

The flattening apparatus 30 can be a polishing device. In some embodiments, the flattening apparatus 30 can be configured to perform a physical polishing process. The flattening apparatus 30 can include a polishing head 31, a rotatable supporting element 32 for supporting the wafer 40, motors 31m and 32m, and controllers 31c and 32c.

In some embodiments, the flattening apparatus 30 can be configured to hold the wafer 40. The flattening apparatus 30 can be electrically coupled to the computer device 20 and configured to flatten the bottom surface 42 of the wafer 40 based on data collected by the stage 10. In some embodiments, the flattening apparatus 30 can be configured to remove foreign objects from the bottom surface 42 of the wafer 40 based on data associated with the bottom surface 42 of the wafer 40 collected by the stage 10. The foreign objects may be introduced by etching, deposition, or diffusion performed on the wafer 40.

In some embodiments, the rotatable supporting element 32 can be configured to hold the wafer 40. For example, the rotatable supporting element 32 may be a vacuum stage configured to fix the wafer 40. In some embodiments, the bottom surface 42 of the wafer 40 can contact the rotatable supporting element 32.

In some embodiments, the rotatable supporting element 32 can be connected to the motor 32m. The motor 32m can be coupled to the controller 32c. In some embodiments, the controller 32c can be configured to control the motor 32m to rotate the rotatable supporting element 32. The rotatable supporting element 32 can be configured to rotate in a predetermined rotational speed. The rotatable supporting element 32 can be configured to rotate in a predetermined turns. For example, the rotatable supporting element 32 can rotate 30 degrees, 60 degrees, quarter turn, half turn, or a full turn. In some embodiments, the motor 32m may be a step motor or the other suitable motors.

The controller 32c can be configured to control the operations of the rotatable supporting element 32, such as a vacuum operation, rotating operation, or other operations. In some embodiments, the controller 32c can be configured to communicate with other elements in the system 3. For example, the controller 32c can be electrically connected to the computer device 20. The controller 32c can be configured to receive instructions from the computer device 20. In some embodiments, the computer device 20 can be configured to cause the rotatable supporting element 32 to perform operations through the controller 32c.

In some embodiments, the polishing head 31 can be configured to polish the bottom surface 42 of the wafer 40. The polishing head 31 can be rotatable for polishing. In some embodiments, the polishing head 31 can be movable in three-dimension. The polishing head 31 can be configured to be operate under different pressures at different locations (i.e., to apply different pressures at different locations of the backside of the wafer 40) in response to data detected from the bottom surface 42 of the wafer 40, such that the bottom surface 42 can be flattened after polish. In some embodiments, the polishing head 31 can be configured to move in an X-Y plane to polish different locations of the wafer. At the same time, the polishing head 31 can be configured to move in a Z-axis to control the polish amount.

Referring to FIG. 3, the polishing head 31 can be connected to the motor 31m. The motor 31m can be coupled to the controller 31c. In some embodiments, the controller 31c can be configured to control the motor 31m to rotate the polishing head 31. The polishing head 31 can be configured to rotate in a predetermined rotational speed. In some embodiments, the motor 31m may be a step motor or the other suitable motors. In some embodiments, the polishing head 31 and the rotatable supporting element 32 can be configured to rotate concurrently.

In another embodiments, to perform the polishing process, it may not be necessary to rotate both of the polishing head 31 and the rotatable supporting element 32. In other words, one of the polishing head 31 and the rotatable supporting element 32 can rotate and another can be at rest. For example, the rotatable supporting element 32 can merely fix the wafer 40 without rotation, and the polishing head 31 can rotate and move in the Z-axis to approach the bottom surface 42 of the wafer 40. On the contrary, the polishing head 31 can merely move in the Z-axis to approach the bottom surface 42 of the wafer 40 without rotation, and the rotatable supporting element 32 can rotate.

The controller 31c can be configured to control the operations of the polishing head 31, such as a rotating operation, a moving operation, or other operations. In some embodiments, the controller 31c can be configured to communicate with other elements in the system 3. For example, the controller 31c can be electrically connected to the computer device 20. The controller 31c can be configured to receive instructions from the computer device 20. In some embodiments, the computer device 20 can be configured to cause the polishing head 31 to perform operations through the controller 31c.

In some embodiments, the controller 31c can be configured to control the polishing head 31 to apply a first pressure to a first location of the wafer 40 in response to data associated with the bottom surface 42. In some embodiments, the first location can be small as a spot. In other embodiments, the first location can have an area of 1 cm² to 3 cm², or even greater. In some embodiments, the first location can be a square, a circle, or other shapes. In some embodiments, the first location may correspond to the size of the polishing head 31. That is, the polishing head 31 can have an area of 1 cm² to 3 cm², or even greater area. The shape of the polishing head 31 can be a square, a circle, or other shapes.

In some embodiments, the controller 31c can be configured to control the polishing head 31 to apply a second pressure, different from the first pressure, to a second location of the wafer 40 different from the first location, in response to data associated with the bottom surface 42. In some embodiments, if the first location is determined to protrude more than the second location, the first pressure can be greater than the second pressure and the polishing head 31 can approach closer to the first location. Accordingly, a greater amount may be removed from the first location of the wafer 40. On the contrary, if the second location is determined to protrude more than the first location, the second pressure can be greater than the first pressure and the polishing head 31 can approach closer to the second location. Accordingly, a greater amount may be removed from the second location of the wafer 40.

Data associated with the bottom surface 42 may include deformation on the bottom surface 42, the flatness of the bottom surface 42, the corresponding location, and the like. Utilizing this data, the controllers 31c and 32c can be configured to control the polishing head 31 and the rotatable supporting element 32 to perform a customized polishing process.

By integrating piezoelectric elements 15, the vacuum stage 10 can detect and collect data regarding flatness and location of the wafer 40. The flattening apparatus 30 can use the data to perform a differentiated polish on the wafer 40, so that the polished wafer 40 can have a flattened surface. The flattening apparatus 30 can be configured to flatten the wafer 40 before an exposure process to be conducted on the wafer. In some embodiments, the flattening operation of the flattening apparatus 30 can be conducted right before the exposure process. Therefore, the defocus situations in subsequent exposures can be reduced, and performance of the exposure, for example, quality of imaging and pattern profiles of the wafer, can be improved.

FIG. 3A is a schematic diagram showing a computer device 20, in accordance with some embodiments of the present disclosure. The computer device 20 may be capable of performing one or more procedures, operations, or methods of the present disclosure. The computer device 20 may be a host computer, a server computer, a client computer, a personal computer (PC), a tablet PC, a set-top box (STB), a personal digital assistant (PDA), a cellular telephone, or a smartphone. In some embodiments, the computer device 20 may be a host computer for controlling different apparatuses of the automated robotic wafer track system. For example, the computer device 20 may be configured to control the controllers 10c, 31c, and 32c.

Referring to FIG. 3A, the computing device 20 includes processor 201, input/output interface 202, communication interface 203, and memory 204. The input/output interface 202 is coupled with the processor 201. The input/output interface 202 allows the user to manipulate the computing device 20 to perform the procedures, operations, or methods of the present disclosure. The communication interface 203 is coupled with the processor 201. The communication interface 203 allows the computing device 20 to communicate with data outside the computing device 20, for example, receiving data including images and/or any essential features. A memory 204 may be a non-transitory computer readable storage medium. The memory 204 is coupled with the processor 201. The memory 204 has stored computer-executable instructions that can be executed by one or more processors (for example, the processor 201).

For example, upon execution of the program instructions stored on the memory 204, the program instructions cause performance of the one or more procedures, operations, or methods disclosed in the present disclosure. For example, the computing device 20 may execute the program instructions to cause the flattening apparatus to flatten the bottom surface 42 of the wafer 40 based on the data collected from the bottom surface 42 of the wafer 40.

FIG. 4A is a schematic top view of a vacuum stage 4, in accordance with some embodiments of the present disclosure. FIG. 4B is a cross-section of the vacuum stage 4 along line A-A of FIG. 4A, in accordance with some embodiments of the present disclosure. Referring to FIGS. 4A and 4B, the vacuum stage 4 includes a body 400, one or more exhaust vents 410 and 420, and piezoelectric elements 450.

The body 400 has a top surface 401 and a bottom surface 402 opposite to the top surface 401. In some embodiments, the vacuum stage 4 can include a layer of piezoelectric elements 450 disposed on the top surface 401 of the body 400. In some embodiments, the piezoelectric elements 450 can cover the top surface 401. In some embodiments, the piezoelectric elements 450 can be electrically connected to a driving and sending circuit (not shown).

The exhaust vents 410 can be recessed from the top surface 401. The exhaust vents 410 can penetrate a portion of the body 400. In some embodiments, the exhaust vents 410 can be arranged in an array. The exhaust vents 410 can be arranged evenly around the center of the vacuum stage 4. For example, four exhaust vents 410 can be arranged in a circle around the center of the vacuum stage 4. In some embodiments, the number of the exhaust vents 410 is not limited.

The exhaust vent 420 can be recessed from the top surface 401. The exhaust vent 420 can penetrate through the body 400. In some embodiments, the exhaust vent 420 can be a primary vent connected to a vacuum pump (not shown). The exhaust vent 420 can be located at the center of the vacuum stage 4. In other embodiments, the exhaust vent 420 can be located at a periphery of the vacuum stage 4. In some embodiments, the number of the exhaust vent 420 is not limited.

In some embodiments, the exhaust vents 410 can be connected to the exhaust vent 420. In some embodiments, the exhaust vent 420 can be connected to or communicated with the vacuum pump. The exhaust vents 410 can be connected to or communicated with the vacuum pump through the exhaust vent 420. Accordingly, negative pressure (e.g., a pressure lower than 1 atm) can be created in the exhaust vents 410 and 420 through the vacuum pump, and the negative pressure can act on the bottom surface of the wafer to suck and fix the wafer. In some embodiments, the vacuum stage 4 can be rectangle, square, circle, or any other shape suitable to the wafer.

In some embodiments, the piezoelectric elements 450 can be disposed on the top surface 401 of the body 400 and between the exhaust vents 410 and 420. In other words, the piezoelectric elements 450 can expose the exhaust vents 410 and 420. The negative pressure in the exhaust vents 410 and 420 can act on the wafer placed on the vacuum stage 4, such that the wafer can be fixed on the piezoelectric elements 450. Accordingly, the piezoelectric elements 450 can sense the data associate with the wafer accurately.

FIG. 5A is a schematic top view of a vacuum stage 5, in accordance with some embodiments of the present disclosure. FIG. 5B is a cross-section of a vacuum stage 5 along line B-B of FIG. 5A, in accordance with some embodiments of the present disclosure. Referring to FIGS. 5A and 5B, the vacuum stage 5 includes a body 500, one or more exhaust channels 510, an exhaust vent 520, and piezoelectric elements 550.

The body 500 has a top surface 501 and a bottom surface 502 opposite to the top surface 501. In some embodiments, the vacuum stage 5 can include a layer of piezoelectric elements 550 disposed on the top surface 501 of the body 500. In some embodiments, the piezoelectric elements 550 can cover the top surface 501. In some embodiments, the piezoelectric elements 550 can be electrically connected to a driving and sending circuit (not shown).

The exhaust channels 510 can be recessed from the top surface 501. The exhaust channels 510 can penetrate a portion of the body 500. In some embodiments, the exhaust channels 510 can be circular. The exhaust channels 510 can be arranged around the center of the vacuum stage 5. In some embodiments, the exhaust channels 510 can have different radiuses. The exhaust channels 510 can be concentric. For example, the vacuum stage 5 can include four exhaust channels 510. In some embodiments, the number of the exhaust channels 510 is not limited.

The exhaust vent 520 can be recessed from the bottom surface 502. In some embodiments, the exhaust vent 520 can be a primary vent connected to a vacuum pump (not shown). The exhaust vent 520 can be located at the center of the vacuum stage 5. In other embodiments, the exhaust vent 520 can be located at a periphery of the vacuum stage 5. In some embodiments, the number of the exhaust vent 520 is not limited.

The exhaust channels 510 can be connected to the exhaust vent 520. In some embodiments, the exhaust vent 520 can be connected to or communicated with the vacuum pump. The exhaust channels 510 can be connected to or communicated with the vacuum pump through the exhaust vent 520. Accordingly, negative pressure (e.g., a pressure lower than 1 atm) can be created in the exhaust channels 510 and the exhaust vent 520 through the vacuum pump, and the negative pressure can act on the bottom surface of the wafer to suck and fix the wafer. In some embodiments, the vacuum stage 5 can be rectangle, square, circle, or any other shape suitable to the wafer.

In some embodiments, the piezoelectric elements 550 can be disposed on the top surface 501 of the body 500 and between adjacent exhaust channels 510. In other words, the piezoelectric elements 550 can expose the exhaust channels 510. The negative pressure in the exhaust channels 510 can act on the wafer placed on the vacuum stage 5, such that the wafer can be fixed on the piezoelectric elements 550. Accordingly, the piezoelectric elements 550 can sense the data associate with the wafer accurately.

FIG. 6A is a schematic top view of a vacuum stage 6, in accordance with some embodiments of the present disclosure. FIG. 6B is a cross-section of a vacuum stage 6 along line C-C of FIG. 6A, in accordance with some embodiments of the present disclosure. Referring to FIGS. 6A and 6B, the vacuum stage 6 includes a body 600, one or more exhaust channels 610, an exhaust vent 620, and piezoelectric elements 650.

The body 600 has a top surface 601 and a bottom surface 602 opposite to the top surface 601. In some embodiments, the vacuum stage 6 can include a layer of piezoelectric elements 650 disposed on the top surface 601 of the body 600. In some embodiments, the piezoelectric elements 650 can cover the top surface 601. In some embodiments, the piezoelectric elements 650 can be electrically connected to a driving and sending circuit (not shown).

The exhaust channels 610 can be recessed from the top surface 601. The exhaust channels 610 can penetrate a portion of the body 600. In some embodiments, the exhaust channels 610 can be linear. The exhaust channels 610 can be a line across the center of the vacuum stage 6. The adjacent exhaust channels 610 can have an included angle of 15, 30, 45, 60, or 90 degrees. For example, the vacuum stage 6 can include four exhaust channels 620. In some embodiments, the number of the exhaust channels 620 is not limited.

The exhaust vent 620 can be recessed from the bottom surface 602. In some embodiments, the exhaust vent 620 can be a primary vent connected to a vacuum pump (not shown). The exhaust vent 620 can be located at the center of the vacuum stage 6. In other embodiments, the exhaust vent 620 can be located at a periphery of the vacuum stage 6. In some embodiments, the number of the exhaust vent 620 is not limited.

The exhaust channels 610 can be connected to the exhaust vent 620. In some embodiments, the exhaust vent 620 can be connected to or communicated with the vacuum pump. The exhaust channels 610 can be connected to or communicated with the vacuum pump through the exhaust vent 620. Accordingly, negative pressure (e.g., a pressure lower than 1 atm) can be created in the exhaust channels 610 and the exhaust vent 620 through the vacuum pump, and the negative pressure can act on the bottom surface of the wafer to suck and fix the wafer. In some embodiments, the vacuum stage 6 can be rectangle, square, circle, or any other shape suitable to the wafer.

In some embodiments, the piezoelectric elements 650 can be disposed on the top surface 601 of the body 600 and between adjacent exhaust channels 610. In other words, the piezoelectric elements 650 can expose the exhaust channels 610. The negative pressure in the exhaust channels 610 can act on the wafer placed on the vacuum stage 6, such that the wafer can be fixed on the piezoelectric elements 650. Accordingly, the piezoelectric elements 650 can sense the data associate with the wafer accurately.

FIG. 7 is a flowchart of a method 7 for manufacturing a semiconductor device, in accordance with some embodiments of the present disclosure. In some embodiments, the method 7 is for flattening a wafer before exposure based on the data of the bottom surface of the wafer detected by a vacuum stage. The method 7 may be performed by an automated robotic wafer track system. For example, the method 7 can be performed by the system 3 of FIG. 3.

The method 7 includes operations 71, 72, 73, 74, and 75. In operation 71, a wafer can be provided. Some pre-treatments (such as, cleaning and pre-heating) can be prepared and conducted on the wafer before photolithography process.

In operation 72, the wafer can be placed on a vacuum stage, wherein a first surface of the wafer is in contact with the vacuum stage. In some embodiments, the first surface of the wafer can be a bottom surface (such as the bottom surface 42 of the wafer 40 of FIG. 3). The wafer may be placed on the stage prior to subsequent operations. In some embodiments, the vacuum stage can be any kind as shown in FIG. 4A-4B, 5A-5B, or 6A-6B. The vacuum stage can fix the bottom surface of the wafer.

In operation 73, the vacuum stage can sense and collect data of the first surface of the wafer. When the wafer is fixed stable on the vacuum stage, the data of the bottom surface of the wafer can be detected. In some embodiment, the vacuum stage can include piezoelectric elements for detecting the topography of the bottom surface of the wafer.

In operation 74, a photoresist process can be performed on the wafer. In some embodiments, the wafer can be covered with photoresist liquid by spin coating. The operation 74 may correspond to operation S2 of FIG. 1.

In operation 75, the first surface of the wafer can be flattened by a polishing device based on the data of the first surface of the wafer. The polishing device can be configured to polish the bottom surface of the wafer in response to the data associated with the bottom surface of the wafer. The operation 75 may correspond to operation S3 of FIG. 1. The polishing device can be configured to flatten the wafer before an exposure process to be conducted on the wafer. In some embodiments, the operation 75 can be conducted right before the exposure process. Because the bottom surface of the wafer is flattened, the performance of the exposure processes, for example, the quality of imaging dimensions and pattern profiles of the wafer, can be improved.

One aspect of the present disclosure provides a system for manufacturing a semiconductor device. The system includes a processor, a stage for supporting a first wafer, and a polishing device. The stage is configured to sense characteristic data of a first surface of the first wafer, wherein the stage is electrically coupled to the processor and configured to transmit the sensed characteristic data of the first surface of the first wafer to the processor. The polishing device is electrically coupled to the processor and configured to remove foreign objects from the first surface of the first wafer based on the sensed characteristic data.

One aspect of the present disclosure provides a system for manufacturing a semiconductor device. The system includes a processor coupled to a non-transitory computer-readable medium storing computer-executable instructions, a stage including piezoelectric elements and electrically coupled to the processor, and a flattening apparatus electrically coupled to the processor and configured to hold the first wafer. The piezoelectric elements are configured to collect data of a first surface of a first wafer supported by the stage. The processor executes the computer-executable instructions and cause the flattening apparatus to flatten the first surface of the first wafer based on data collected from the first surface of the first wafer.

One aspect of the present disclosure provides a method for manufacturing a semiconductor device. The method includes: providing a wafer, placing the wafer on a vacuum stage, wherein a first surface of the wafer is in contact with the vacuum stage, the vacuum stage sensing and collecting based on data of the first surface of the wafer, performing a photoresist process on the wafer and a polishing device flattening the first surface of the wafer based on data of said surface.

The embodiments of the present disclosure provide systems and methods for flattening a backside of a wafer before exposure to avoid undesired variations from foreign objects/particles, film residue, uneven film, and other contaminants and defects on the backside of the wafer as introduced by etching, deposition, diffusion, or the like, which lead to defocusing at some parts of the wafer.

The system of the present disclosure provides a supporting stage (such as a vacuum stage) and a flattening apparatus (such as a polishing device). The supporting stage is capable of detecting and collecting the flatness of the backside of the wafer and the corresponding location. The supporting stage can include piezoelectric elements configured to sense a topography of the backside of the wafer. For example, the piezoelectric elements can be configured to detect deformations on the backside of the wafer. The deformations on the backside of the wafer can be resulted from the foreign objects or uneven film. The piezoelectric data corresponding to the deformations can be converted to data associated with the flatness and location, such that the supporting stage can collect the flatness and location data of the backside of the wafer.

Gathered data regarding flatness and location can be transmitted to the flattening apparatus, which can polish the backside of the wafer accordingly, based on the topography thereof under different pressures. That is, the flattening apparatus can polish each portion of the backside of the wafer, in response to a respective deformation and the corresponding location. Accordingly, the result is a flattened surface with improved flatness, such that undesired defocus issues in the exposure processes can be reduced. Comparing to fixed pressure polishing, the disclosed system also avoids over polishing that can damage the wafer. Thus, the performance of the exposure processes, for example, the quality of the imaging dimensions and the pattern profiles of the wafer, can be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A system for manufacturing a semiconductor device, the system comprising:
a processor coupled to a non-transitory computer-readable medium storing computer-executable instructions;
a stage including piezoelectric elements and electrically coupled to the processor, wherein the piezoelectric elements are configured to collect data of a first surface of a first wafer supported by the stage; and
a flattening apparatus electrically coupled to the processor and configured to hold the first wafer,
wherein the processor executes the computer-executable instructions to cause the flattening apparatus to flatten the first surface of the first wafer based on the data collected from the first surface of the first wafer.

2. The system of claim 1, wherein the piezoelectric elements are disposed on a top surface of the stage and configured to be in contact with the first surface of the first wafer when the first wafer is placed on the stage.

3. The system of claim 1, wherein each of the piezoelectric elements has an area in a range of 1 mm² to 100 mm² in a top view.

4. The system of claim 1, wherein the piezoelectric elements are configured to sense a deformation on the first wafer in a nanometer scale.

5. The system of claim 1, wherein the flattening apparatus is configured to perform a physical polishing process.

6. The system of claim 1, wherein the flattening apparatus comprises:
a polishing head; and
a controller coupled to the polishing head, wherein the controller is configured to control the polishing head to apply a first pressure to a first location of the first wafer in response to the data collected from the first surface of the first wafer.

7. The system of claim 6, wherein the controller is configured to control the polishing head to apply a second pressure different from the first pressure to a second location different from the first location of the first wafer, in response to the data collected from the first surface of the first wafer.

8. The system of claim 6, wherein the polishing head is movable in three-dimension.

9. The system of claim 6, wherein the flattening apparatus further comprises a rotatable supporting element configured to hold the first wafer.

10. The system of claim 6, wherein the polishing head is rotatable.

11. The system of claim 1, wherein the flattening apparatus is configured to flatten the first wafer before an exposure process to be conducted on the first wafer.

12. The system of claim 1, wherein the first surface of the wafer is a backside surface.

13. The system of claim 1, wherein the flattening apparatus is configured to remove foreign objects from the first surface of the first wafer, wherein the foreign objects are introduced by an etching process, a deposition process, or a diffusion process that has performed on the wafer.
